(19) United States
(12) Patent Application Publication
(10) Pub. No.: US 2001/0054389 A1
(43) Pub. Date: Dec. 27, 2001

(54) Electro-static chucking mechanism and surface processing apparatus

(76) Inventors: Yasumi Sago, Tokyo (JP); Masayoshi Ikeda, Tokyo (JP); Kazuaki Kaneko, Tokyo (JP); Hiroki Date, Ibaraki (JP)

Correspondence Address: KANESAKA AND TAKEUCHI, 727 Twenty-Third Street South, Arlington, VA, 22202, US

(21) Appl. No.: 09/879,934

(22) Filed: Jun. 14, 2001

(30) Foreign Application Priority Data
Jun. 14, 2000 (JP) 2000-179191
Apr. 20, 2001 (JP) 2001-122189

(51) Int. Cl. C23C 16/00; B05C 13/00

(52) U.S. Cl. 118/728; 118/500

(57) ABSTRACT

This invention presents an ESC mechanism for chucking an object electro-statically on a chucking surface, comprising a stage having a dielectric block of which surface is the chucking surface, and a chucking electrode provided in the dielectric block. A temperature controller is provided with the stage for controlling temperature of the object. A chucking power source to apply voltage to the chucking electrode is provided so that the object is chucked. The chucking surface has concaves of which openings are shut by the chucked object. A heat-exchange gas introduction system that introduces heat-exchange gas into the concaves is provided. The concaves include a heat-exchange concave for promoting heat-exchange between the stage and the object under increased pressure, and a gas-diffusion concave for making the introduced gas diffuse to the heat-exchange concave. The gas-diffusion concave is deeper than the heat-exchange concave. This invention also presents a surface processing apparatus, comprising a process chamber in which a surface of an object is processed, and the electro-static chucking mechanism of the same composition.

### BACKGROUND OF THE INVENTION

The invention of this application relates to an electro-static chucking (ESC) mechanism for chucking an object electro-statically on a chucking surface. Especially, this invention relates to such an ESC mechanism having heat-exchange function to the object as one that is incorporated into a surface processing apparatus.

The electro-static chucking technique is widely used for automatically holding location of an object without damage. Especially, various kinds of surface processing apparatuses utilize the electro-static chucking technique to hold a substrate as the object at a certain position. The electro-static chucking mechanism usually comprises a ESC stage on which the object is chucked, and a chucking power source to apply voltage to the ESC stage for chucking the object. The ESC stage is roughly composed of a main body, a dielectric block fixed with the main body, and a couple of chucking electrodes provided within the dielectric block. Static electricity is induced on the dielectric block by voltage applied to the chucking electrodes, thereby chucking the object.

Such the electro-static chucking mechanism some times has heat-exchange function between the object and the ESC stage. Surface processing apparatuses, for example, often employ the structure that a heater is provided within the ESC stage, or coolant is circulated through the ESC stage, for controlling temperature of the object in a specific range during the process. For the temperature control of the object, the heater is usually negative feedback controlled. The coolant is maintained at a specific low temperature.

In such the temperature control, there arises the problem that accuracy or efficiency of the temperature control decreases, when heat exchange between the ESC stage and the object is insufficient. Particularly in the surface processing apparatuses, the object is sometimes processed under vacuum environment within a process chamber. Minute gaps exist between the ESC stage and the object because those interfaces are not completely flat. The heat exchange through the gaps is very poor because those are at vacuum pressure. Therefore, the heat exchange efficiency between the ESC stage and the object is lower than the case those are at the atmosphere.

To solve this problem, a kind of surface processing apparatuses employs the structure that heat-exchange gas is introduced between the ESC stage and the object. The surface of the ESC stage, which is the chucking surface, has a shallow concave. Here, “chucking surface” in this specification means the surface of the side at which the object is chucked. Not always the object is chucked on the whole area of the chucking surface. The opening of the concave is shut with the chucked object. The ESC stage has a gas-introduction channel, through which the heat-exchange gas is introduced into the concave.

In the above-described ESC mechanism, depth of the concave is preferably small. In the concave, the heat-exchange gas molecules need to travel between the bottom of the concave and the object for the heat exchange. If the concave is deeper, the gas molecules must travel longer, making possibility of dispersion by mutual collision higher. As a result, the heat-exchange efficiency decreases.

On the other hand, the heat-exchange gas is introduced into the concave from the outlet of the gas-introduction channel, which is provided on the bottom of the concave. The heat-exchange gas diffuses along directions parallel to the chucking surface, filling the concave. To fill the concave with the heat-exchange gas uniformly, conductance of the heat-exchange gas along the diffusion directions needs to be high enough. However, when the concave is shallower, the conductance of the heat-exchange gas may decrease. Therefore, the heat-exchange gas cannot diffuse uniformly, resulting in that pressure in the concave becomes out of uniform along the directions parallel to the chucking surface. This leads to temperature non-uniformity of the object along those directions. This often means, in the surface processing apparatuses, which the process of the object becomes out of uniform.

### SUMMARY OF THE INVENTION

Object of this invention is to solve the problems described above.

To accomplish this object, the invention presents an ESC mechanism for chucking an object electro-statically on a chucking surface, comprising a stage having a dielectric block of which surf ace is the chucking surf ace, and a chucking electrode provided in the dielectric block. A temperature controller is provided on the stage for controlling temperature of the object. A chucking power source to apply voltage to the chucking electrode is provided so that the object is chucked. The chucking surface has concaves of which openings are shut by the chucked object. A heat-exchange gas introduction system that introduces heat-exchange gas into the concaves is provided. The concaves include a heat-exchange concave for promoting heat-exchange between the stage and the object under increased pressure, and a gas-diffusion concave for making the introduced gas diffuse to the heat-exchange concave. The gas-diffusion concave is deeper than the heat-exchange concave.

Further to accomplish the object, the invention also presents a surface processing apparatus, comprising a process chamber in which a surface of an object is processed, and the electro-static chucking mechanism of the same composition.

### BRIEF DESCRIPTION OF DRAWINGS

FIG. 2 is a front cross-sectional view schematically showing an electro-static mechanism of the embodiment of the invention.

FIG. 2 is a plane view of the ESC stage 2 shown in FIG. 1.

FIG. 3 is a side cross-sectional view on A-A shown in FIG. 2, explaining the concave-convex configuration on the chucking surface of the ESC stage 2.

FIG. 4 is a side cross-sectional view on B-B shown in FIG. 2, explaining the concave-convex configuration on the chucking surface of the ESC stage 2.

FIG. 5 is a side cross-sectional view on C-C shown in FIG. 2, explaining the concave-convex configuration on the chucking surface of the ESC stage 2.

FIG. 6 is a schematic plane cross-sectional view explaining the configuration of the cooling cavity 200 within the main body 21.

FIG. 7 is a schematic front cross-sectional view of a surface processing apparatus of the embodiment of the invention.

### DETAILED DESCRIPTION OF THE PREFERRED EMBODIMENTS

The preferred embodiments of the invention are described as follows.

The ESC mechanism shown in FIG. 1 comprises an ESC stage 2 of which surface is the chucking surface, and a chucking power source 3 to apply voltage so that the object can be chucked. The ESC stage 2 is roughly composed of a main body 21, a dielectric block 22 fixed with the main body 21, and a couple of chucking electrodes 23,23 provided in the dielectric block 22.

The main body is made of metal such as stainless steel or aluminum. The dielectric block is made of dielectric such as alumina. A sheet 29 made of eutectic alloy including indium, or low-melting-point metal or alloy is inserted between the main 21 body and the dielectric block 22. The sheet 29 is to enhance heat transfer by filling the gap between the main body 21 and the dielectric block 22. The chucking electrodes 23,23 are the boards provided in parallel to the chucking surface. It is preferable that configuration and arrangement of the chucking electrodes 23,23 are symmetrically coaxial with the center of the ESC stage 2.

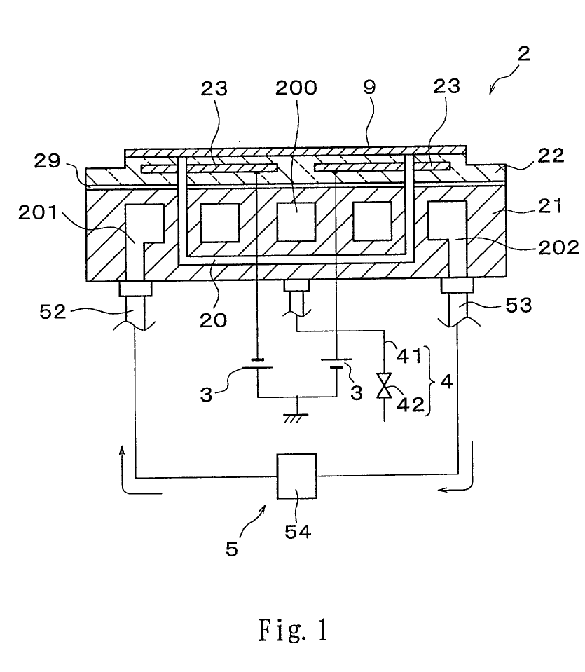

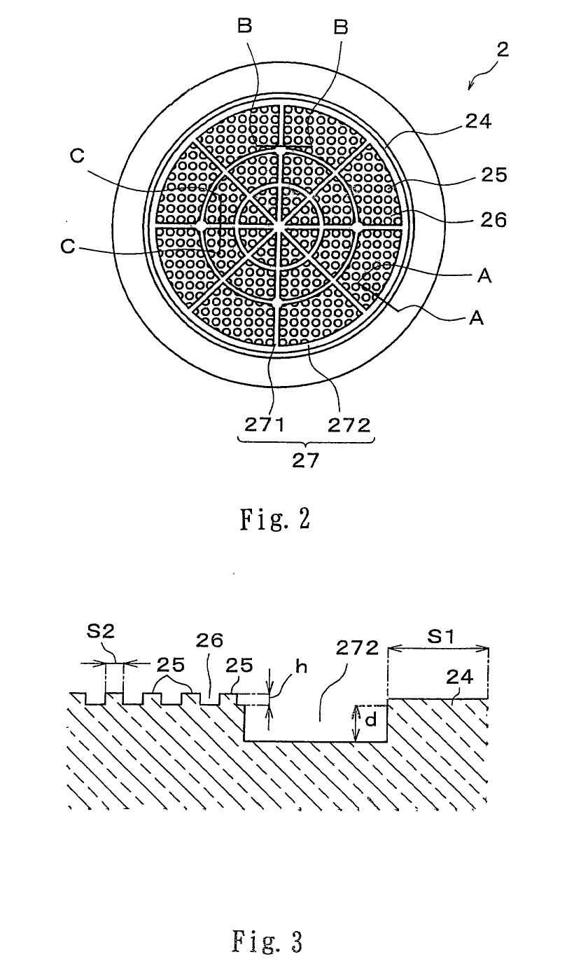

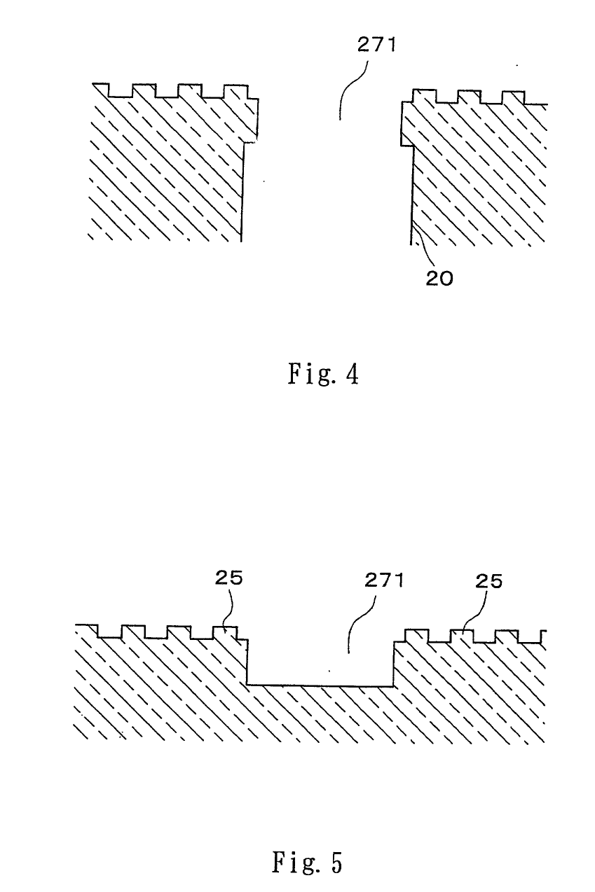

What much characterizes this embodiment is in configuration of the chucking surface of the ESC stage 2. This point is described using FIG. 1 to FIG. 5 as follows. Though the chucking surface of the ESC stage 2 appears flat in FIG. 1 actually it has concave-convex configuration. FIG. 2 shows a plane view of this configuration. FIG. 3, FIG. 4 and FIG. 5 show a side cross-sectional configuration of the chucking surface in detail. FIG. 3 is the cross-section on A-A shown in FIG. 2. FIG. 4 is the cross-section on B-B shown in FIG. 2. FIG. 5 is the cross-section on C-C shown in FIG. 2. The upper surface of the dielectric block 22 corresponds to the chucking surface. As shown in FIG. 1, the dielectric block 22 protrudes upward as a whole. The object 9 is chucked on the top of the protrusion. Therefore, the top surface of the protrusion is the chucking surface.

As shown in FIG. 2, the plane view of the chucking surface is circular as a whole. The object 9 is circular as well, having nearly the same radius as the chucking surface. The dielectric block 22 has a circumferential convex 24 along the outline of the circular chucking surface. The convex 24 is herein after called “marginal convex”. Inside the marginal convex 24, many small column-shaped convexes 25 are formed. Each of the convexes 25 is hereinafter simply called “column convex”. As shown in FIG. 3, the top surface of the marginal convex 24 and the top surface of each column convex 25 are the same in height. When chucked, the object 9 is in contact with both of the top surfaces. Therefore, in this embodiment, the chucking surface is composed of the top surface of the marginal convex 24 and the top surface of each column convex 25. When the object 9 is chucked, the concave 26 formed of the marginal convex 24 and the column convexes 25 is shut by the object 9.

The concave 26 formed of the marginal convex 24 and the column convexes 25 is the one for promoting the heat exchange between the ESC stage 2 and the object 9. This concave 26 is hereinafter called “heat-exchange concave”. What characterizes this embodiment is that another concave 27 is provided in addition to the heat-exchange concave 26 so that the heat-exchange gas can diffuse efficiently to be introduced uniformly into the heat-exchange concave 26. The concave 27 is hereinafter called “gas-diffusion concave”.

As shown in FIG. 2, the gas-diffusion concave 27 is composed of spoke-like-shaped trenches 271 radiate from the center of the ESC stage 2, and trenches 272 which are circumferential and coaxial with the ESC stage 2. Each trench 271 is hereinafter called “radiate part”, and each trench 272 is hereinafter called “circumferential part”. The most outer circumferential part 272 is provided just inside the marginal convex 24.

As shown FIG. 3 to FIG. 5, the gas-diffusion concave 27 is deeper than the heat-exchange concave 26. A gas-introduction channel 20 is provided at the position where its outlet is at the bottom of the gas-diffusion concave 27. The gas-introduction channel 20 is lengthened perpendicularly to the chucking surface. In this embodiment, the gas-introduction channel is split into four, having four outlets. As shown in FIG. 2, the four outlets are located at every 90 degree on the second outer circumferential part 272. As understood from FIG. 2 and FIG. 4, diameter of the outlet of the gas-introduction channel is a little larger than width of the gas-diffusion concave 27.

As shown in FIG. 1, the ESC mechanism comprises a heat-exchange gas introduction system 4. The heat-exchange gas introduction system 4 is composed of a gas-introduction pipe 41 connected with the inlet of the gas-introduction channel 20, a gas bomb (not shown) connected with the gas-introduction pipe 41, a valve 42, a mass-flow controller (not shown) and a filter (not shown) provided on the gas-introduction pipe 41, and other components. As the heat-exchange gas, helium is adopted in this embodiment.

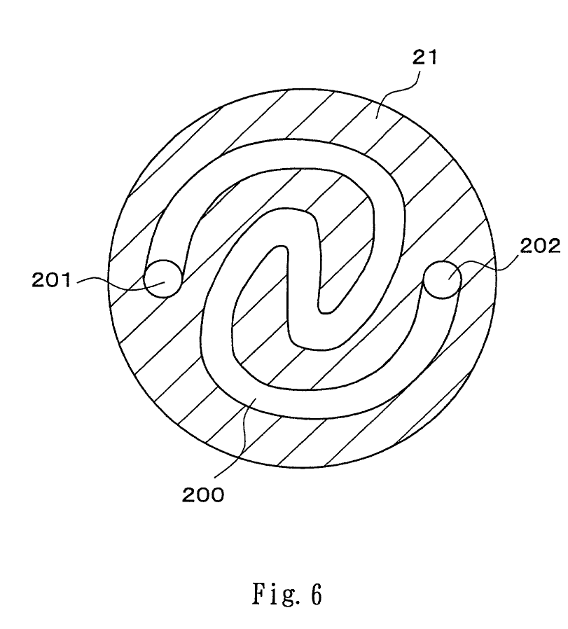

The ESC stage 2 comprises a temperature controller 5 that controls temperature of the object 9, cooling the object 9. The temperature controller 5 circulates coolant through a cavity 200 within the ESC stage 2. The cavity 200 is provided with the main body 21. As shown in FIG. 6, the cavity 200 is snaked so that the ESC stage can be cooled uniformly. One end of the cavity 200 is the coolant inlet 201, and the other end of the cavity is the coolant outlet 202. A coolant introduction pipe 52 is connected with the coolant inlet 201, and a coolant drainage pipe 53 is connected with the coolant outlet 202. A circulator 54 is provided. The circulator 54 feeds the coolant flowing out of the coolant outlet 202 to the coolant inlet 201 through the coolant introduction pipe 52 after cooling down the coolant at the specific temperature. Because the cooled coolant flows through the cavity 200, the ESC stage 2 is maintained at a specific low temperature as a whole. As a result, the object 9 is cooled as well.

Next, operation of the ESC mechanism of this embodiment is described. First, the object 9 is placed on the ESC stage 2. The center axis of the object 9 and the center axis of the ESC stage 2 are made correspond to each other. In this embodiment, the outline of the protrusion of the dielectric block 22 and the outline of the object 9 correspond to each other as well. The inside space of the marginal convex 24 is shut by the object 9, thereby forming closed space. “Closed space” means space essentially having no opening other than the outlet of the gas-introduction channel 20.

Afterward, the chucking power source 3 is operated to apply voltage to the chucking electrodes 23,23. As a result, static electricity is induced on the chucking surface, thereby chucking the object 9 electro-statically. The chucked object 9 is cooled because the temperature controller 5 has been operated in advance. In addition, the gas-introduction system 4 is operated to introduce the heat-exchange gas into the concaves 26,27. As a result, the object 9 is cooled efficiently because pressure in the concaves 26,27 is increased.

In removing the object 9 from the ESC stage 2, the operation of the chucking power source 3 is stopped after the operation of the gas-introduction system 4 is stopped. Then, the object 9 is removed from the ESC stage 2. If residual charges on the chucking surface cause trouble, oppositely biasing voltage is applied to the chucking electrodes 23,23, thereby promoting vanishment of the residual charges.

In the ESC mechanism of the above-described embodiment, temperature of the object 9 can be maintained highly uniform without making the heat-exchange efficiency decrease, because the gas-diffusion concave 27 is provided in addition to the heat-exchange concave 26. If there is only the heat-exchange concave 26, conductance of the heat-exchange gas becomes small, resulting in that pressure in the heat-exchange concave 26 becomes out of uniform because the heat-exchange gas is not supplied uniformly enough in the heat-exchange concave 26. Therefore, temperature of the object 9 becomes out of uniform as well. To solve this problem, the heat-exchange concave 26 may be deeper, i.e. the height of the marginal convex 24 and the column convexes 25 may be higher. However, if the heat-exchange concave 26 is made deeper, the heat-exchange gas molecules need to travel longer distance, making the heat-exchange efficiency lower.

Contrarily in this embodiment, the heat-exchange gas initially reaches to the gas-diffusion concave 27. Then, the heat-exchange gas is introduced into the heat-exchange concave 26, diffusing in the gas-diffusion concave 27. Because the gas-diffusion concave 27 is deeper than the heat-exchange concave 26, conductance in the gas-diffusion concave 27 is higher than the heat-exchange concave 26. Therefore, the heat-exchange gas is introduced into the heat-exchange concave 26 efficiently, thereby increasing pressure in the heat-exchange concave 26 efficiently. This is why temperature of the object 9 can be maintained highly uniform without reducing the heat-exchange efficiency.

Next, using FIG. 3 and FIG. 4, sizes of the heat-exchange concave 26 and the gas-diffusion concave 27 are described. The height h of the marginal convex 24 and the column convex 25 is preferably about 1 to 20 μm. When the height h is over 20 μm, the heat-exchange gas molecules need to travel longer distance for the heat exchange as described, reducing the heat-exchange efficiency. When the height h is below 1 μm, conductance in the heat-exchange concave 26 decreases much, making temperature of the object 9 out of uniform. Concretely, pressure in the heat-exchange concave 26 is higher at a region near the gas-diffusion concave 27, and lower at a region far from the gas-diffusion concave 27 because of shortage of the gas molecules. As a result, temperature of the object 9 becomes out of uniform as well.

Prudent consideration is necessary for amount area of the top surfaces of the marginal convex 24 and the column convexes 25 with respect to obtaining sufficient chucking force. Area of the object 9 in contact with the ESC stage 2 when chucked is hereinafter called “contact area”. The whole surface area of the object 9 facing to the ESC stage 2 is hereinafter called “whole facing area”. The ratio of the contact area to the facing area is hereinafter called “area ratio”. Generally speaking, the area ratio is preferably 3 to 20%. In this embodiment, when the top surface area of the marginal convex 24 is S1, the top surface area of each column convex is S2, the whole facing area is S3, and the number of the column convexes 25 is n, then the area ratio R, which is

R={(S1+S2·n)/S3}·100,

would be preferably 3 to 20%.

If the area ratio R is small, the whole chucking force becomes week because the surface area on which charges are induced is reduced. If the area ratio is below 3% in case that pressure in the heat-exchange concave 26 is increased for the good heat-exchange, it is required to chuck the object 9 with very high voltage, which is unpractical and difficult. On the other hand, the area ratio R is increased over 20%, the heat-exchange concave 26 is made too small, losing the effect of the heat-exchange efficiency improvement by the high-pressure heat-exchange concave 26.

Size of the gas-diffusion concave 27 needs prudential consideration as well with respect to obtaining the sufficient heat-exchange efficiency. If size of the gas-diffusion concave 27 is enlarged much, the sufficient heat-exchange cannot be obtained, because it is the space to enhance the gas-diffusion efficiency, sacrificing the heat-exchange efficiency. With this respect, when area of the gas-diffusion concave 27 along the chucking surface is S4, which is hereinafter simply called “cross-sectional area”, S4 is preferably 30% or less against the whole area of the chucking surface, which corresponds to the area S3 of the bottom surface of the object 9. The cross-sectional area S4 is amount of eight radiate parts 271 and three circumferential parts 272.

Contrarily, the cross-sectional area S4 is made too small, it is impossible to obtain the effect of the gas-introduction uniformity by increasing the conductance. Generally, conductance of gas is proportional to area of cross section perpendicular to diffusion direction. In this embodiment, the smaller cross-sectional area S4 means that width of the gas-diffusion path is made narrow, resulting in that the conductance is reduced. Considering this point, the cross-sectional area S4 is preferably 5% or more against the whole area of the chucking surface. If S4 is over 30% against the whole area of the chucking surface, the heat-exchange efficiency may decrease too much, because it means the area of the heat-exchange concave 26 is made too small relatively. Therefore, S4 is preferably 30% or less against the whole area of the chucking surface. The whole area S of the chucking surface is;

S=S1+S2·n+S4+S5=S3

Depth of the gas-diffusion concave 27, which is designated by “d” in FIG. 3, is preferably 50 to 1000 μm. If the depth d is below 50 μm, the effect of the temperature uniformity is not obtained sufficiently, because the conductance in the gas-diffusion concave 27 can not be made higher enough than the heat-exchange concave 26. If the depth d is over 1000 μm, the conductance may increase excessively. Under the excessively high conductance, it is difficult to make pressure in the heat-exchange concave 26 high enough, bringing the problem that the heat-exchange efficiency is not improved sufficiently.

In the described operation of the ESC mechanism, the heat-exchange gas is preferably confined within the concaves 26,27. If the heat-exchange gas is not confined, it means that the object 9 floats up from the chucking surface by pressure of the heat-exchange gas. If such the float-up takes place, chuck of the object 9 becomes unstable. Additionally, the heat-exchange efficiency is made worse because heat contact of the ESC stage 2 and the object 9 becomes insufficient. Therefore, it is preferable to introduce the heat exchange gas as far as it does not leak out of the concaves 26,27, or to control pressure of the heat-exchange gas so that the gas leak can be limited within bringing no matter.

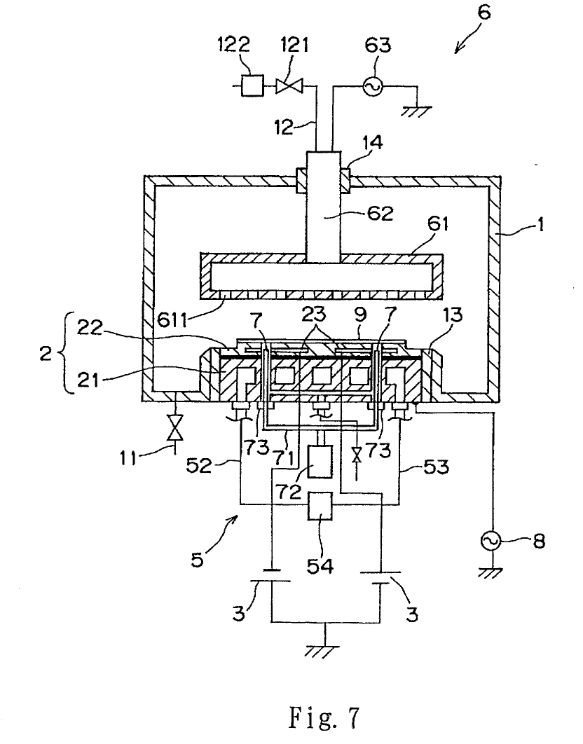

Next, the embodiment of the surface processing apparatus of the invention is described using FIG. 7. FIG. 7 is a schematic front cross-sectional view of a surface processing apparatus of the embodiment of the invention. This embodiment of the surface processing apparatus comprises the above-described ESC mechanism. Though the above described ESC mechanism can be utilized for various kinds of surface processing apparatuses, an etching apparatus is adopted as an example in the following description. Therefore, the apparatus shown in FIG. 7 is the etching apparatus.

Concretely, the apparatus shown in FIG. 7 is roughly composed of a process chamber 1 comprising a pumping system 11 and a process-gas introduction system 12, the ESC mechanism holding the object 9 at a position in the process chamber 1, and a power supply system 6 for generating plasma in the process chamber 1, thereby etching the object 9.

The process chamber is the airtight vacuum chamber, with which a load-lock chamber (not shown) is connected interposing a gate valve (not shown). The pumping system 11 can pump the process chamber 1 down to a specific vacuum pressure by a turbo-molecular pump or diffusion pump. The process-gas introduction system 12 comprises a valve 121 and a mass-flow controller 122. The process-gas introduction system 12 introduces fluoride gas such as tetra fluoride, which has the etching effect, at a specific flow rate.

Composition of the ESC mechanism is essentially the same as the described one. The ESC stage 2 is provided air-tightly shutting an opening of the process chamber 1 interposing the insulation member 13. In this embodiment, lift pins 7 are provided within the ESC stage 2 for receiving and passing the object 9. Each lift pin 7 is arranged uprightly, being apart at the equal degree on a circumference coaxial with the ESC mechanism. In this embodiment, not to make structure of the ESC stage 2 complicated, each lift pin 7 is provided in each gas-introduction channel 20. Therefore, the number of the lift pins 7 is four.

The bottom of each lift pin 7 is fixed with a baseboard 71 posing horizontally. A linear-motion mechanism 72 is provided with the baseboard 71. The linear-motion mechanism 72 is operated to lift up or down the four lift pins 7 together. The gas-introduction channel 20 has a side hole through which the heat-exchange gas introduction system 4 introduces the heat-exchange gas. A seal member 73 such as a mechanical seal is provided at the bottom opening of the gas-introduction channel 20, allowing the up-and-down motion of the lift pins 7.

The power supply system 6 is roughly composed of a process electrode 61 provided in the process chamber 1, a holder 62 holding the process electrode 61, a process power source 63, and other components. The process electrode 61 is the short cylindrical member, which is provided in coaxial with the ESC stage 2. The holder 62 penetrates air tightly through the process chamber 1, interposing an insulation member 14. The process electrode 61 is commonly used as the member for introducing the process gas uniformly. Many gas-effusion holes are formed uniformly on the bottom of the process electrode 61. The process-gas introduction system 12 feeds the process gas into the process electrode 61 via the holder 62. After being stored in the process electrode 61 temporarily, the process gas effuses uniformly from each gas-effusion hole 611.

A High-Frequency power source is employed as the process power source 63. Here, frequencies between LF (Low Frequency) and UHF (Ultra-High Frequency) are defined as HF (High Frequency). When the HF power source applies HF voltage to the process electrode 61, HF discharge is ignited with the process gas, thereby generating the plasma. For example, when the process gas is fluoride gas, fluoride radicals or ions are produced in the plasma. Those radicals or ions reach to the object 9, thereby etching the surface of the object 9.

This embodiment employs a component to apply the self-bias voltage to the object 9 for the efficient etching. Concretely, the chucking power source 3 is connected with the chucking electrodes 23,23 to chuck the object 9. In addition to this, a self-bias HF power source 8 is connected with the main body 21 made of metal. When the HF field is applied via the main body 21 by the self-bias HF power source 8, the self-bias voltage, which is negative direct voltage, is given to the object 9 through the mutual reaction of the plasma and the HF field. The ions in the plasma are extracted and accelerated to the object 9. As a result, the highly efficient etching such as the reactive ion etching can be carried out.

During the etching, the object 9 may suffer thermal damage when it is heated excessively by the plasma. For example, in case the object 9 is a semiconductor wafer, an element or circuit already formed on the object 9 is thermally deteriorated, leading to malfunction. To avoid such the problem, the ESC mechanism cools the object 9 at a specific temperature during the etching. As described, are ESC mechanism circulates the temperature-controlled coolant, thereby cooling down the object 9 through the ESC stage 2. In this cool down, because the chucking surface of the ESC stage 2 has the gas-diffusion concave 27 in addition to the heat-exchange concave 26, not only the cool down is carried out efficiently but also temperature of the object 9 is maintained highly uniform. Therefore, high uniformity of the etching process is also enabled.

Though this embodiment employs the temperature controller to cool the object 9, another temperature controller to heat the object 9 may be employed. In this case, a resistance heater or lamp heater is provided with the ESC stage 2. Though this embodiment is the twin-electrode type ESC mechanism, the sole-electrode type can be employed as well. Even in case of the sole-electrode type, the object 9 can be chucked because the plasma acts as an opposite electrode. Besides, the multi-couple-electrode type where a multiple couple of electrodes are provided may be employed. The object 9 can be chucked even by applying HF voltage with the chucking electrode, when plasma is generated at the space over the object 9.

Though the etching is adopted as the surface process in the above description, this invention can be applied to thin film deposition processes such as the sputtering and the chemical vapor deposition (CVD), surface denaturalization processes such as the surface oxidation and surface nitriding, and the ashing process as well. Beside a semiconductor wafer, the object 9 may be a substrate for a liquid crystal display or a plasma display, and a substrate for a magnetic device such as a magnetic head. The ESC mechanism of this invention can be comprised of an instrument for analysis, i.e. an instrument analyzing an object, as chucking it electro-statically.

What is claimed is:

1. An electro-static chucking mechanism for chucking an object electro-statically on a chucking surface, comprising:
a stage having a dielectric block of which surface is said chucking surface, and a chucking electrode provided in said dielectric block;
a temperature controller provided with said stage for controlling temperature of said object;
a chucking power source to apply voltage to said chucking electrode so that said object is chucked;
wherein,
said chucking surface has concaves of which openings are shut by said chucked object,
a heat-exchange gas introduction system that introduces heat-exchange gas into said concaves is provided,
said concaves include a heat-exchange concave for promoting heat-exchange under increased pressure and a gas-diffusion concave for making said introduced gas diffuse to said heat-exchange concave, and
said gas-diffusion concave is deeper than said heat-exchange concave.

2. An electro-static chucking mechanism as claimed in claim 1, wherein
said gas-diffusion concave is formed in coaxial with the center of said stage.

3. An electro-static chucking mechanism as claimed in claim 1, wherein;
depth of said heat-exchange concave is in the range of 1 to 20 μm.

4. An electro-static chucking mechanism as claimed in claim 1, wherein;
area of said chucking surface in contact with said chucked object is in the range of 3 to 20% against surface area of said object facing to said stage.

5. An electro-static chucking mechanism as claimed in claim 1, wherein;
cross-sectional area of said gas-diffusion concave along said chucking surface is in the range of 5 to 30% against surface area of said object facing to said stage.

6. An electro-static chucking mechanism as claimed in claim 1, wherein;
depth of said gas-diffusion concave is in the range of 50 to 1000 μm.

7. An electro-static chucking mechanism for chucking an object electro-statically on a chucking surface, comprising:
a stage having a dielectric block of which surface is said chucking surface, and a chucking electrode provided in said dielectric block;
a temperature controller provided with said stage for controlling temperature of said object;
a chucking power supply to apply voltage to said chucking electrode to chuck said object;
wherein,
said chucking surface has a concave of which opening is shut by said chucked object,
said stage has a gas introduction channel reaching to said concave,
a gas introduction system that introduces heat-exchange gas into said concave through said gas introduction channel is provided for increasing pressure in said concave,
a lift pin for receiving and passing said object is provided in said gas introduction channel.

8. A surface processing apparatus, comprising:
a process chamber in which a surface of an object is processed, and
an electro-static chucking mechanism for chucking said object electro-statically on a chucking surface in said process chamber,
wherein:
said mechanism comprises a stage having a dielectric block of which surface is said chucking surface, and a chucking electrode provided in said dielectric block;
a temperature controller is provided with said stage for controlling temperature of said object;
a chucking power source to apply voltage to said chucking electrode is provided so that said object is chucked;
said chucking surface has concaves of which openings are shut by said chucked object;
a heat-exchange gas introduction system that introduces heat-exchange gas into said concaves is provided;
said concaves include a heat-exchange concave for promoting heat-exchange under increased pressure and a gas-diffusion concave for making said introduced gas diffuse to said heat-exchange concave; and
said gas-diffusion concave is deeper than said heat-exchange concave.

9. A surface processing apparatus as claimed in claim 8, wherein
said gas-diffusion concave is formed in coaxial with the center of said stage.

10. A surface processing apparatus as claimed in claim 8, wherein;
depth of said heat-exchange concave is in the range of 1 to 20 μm.

11. A surface processing apparatus as claimed in claim 8, wherein
area of said chucking surface in contact with said object is in the range of 3 to 20% against surface area of said object facing to said stage.

12. A surface processing apparatus as claimed in claim 8, wherein
cross-sectional area of said gas-diffusion concave along said chucking surface is in the range of 5 to 30% of surface area of said object facing to said stage.

13. A surface processing apparatus as claimed in claim 8, wherein
depth of said gas-diffusion concave is in the range of 50 to 1000 μm.

14. A surface processing apparatus, comprising:
a process chamber in which a surface of an object is processed, and
an electro-static chucking mechanism for chucking said object electrostatically on a chucking surface in said process chamber,
wherein:
said mechanism comprises a stage having a dielectric block of which surface is said chucking surface, and a chucking electrode provided in said dielectric block;
a temperature controller is provided with said stage for controlling temperature of said object;
a chucking power source to apply voltage to said chucking electrode is provided so that said object is chucked;
said chucking surface has a concave of which opening is shut by said chucked object,
said stage has a gas introduction channel reaching to said concave,
a gas introduction system that introduces heat-exchange gas into said concave through said gas introduction channel is provided for increasing pressure in said concave,
a lift pin for receiving and passing said object is provided in said gas introduction channel.
